(19) United States
(12) Patent Application Publication
(10) Pub. No.: US 2009/0314211 A1
(43) Pub. Date: Dec. 24, 2009

(54) BIG FOOT LIFT PIN

(75) Inventors: Dale R. Du Bois, Los Gatos, CA (US); Mark A. Fodor, Los Gatos, CA (US); Karthik Janakiraman, San Jose, CA (US); Juan Carlos Rocha-Alvarez, San Carlos, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/483,845

(22) Filed: Jun. 12, 2009

Related U.S. Application Data
(60) Provisional application No. 61/075,225, filed on Jun. 24, 2008.

(51) Int. Cl. C23C 16/458; B23Q 1/44

(52) U.S. Cl. 118/729; 269/74

(57) ABSTRACT

Embodiments described herein generally provide a lift pin assembly having increased wafer placement accuracy, repeatability, reliability, and corrosion resistance. In one embodiment, a lift pin assembly for positioning a substrate relative to a substrate support is provided. The lift pin assembly comprises a lift pin comprising a pin shaft, a pin head coupled with a first end of the pin shaft for supporting the substrate, and a shoulder coupled with a second end of the pin shaft. The lift pin assembly further comprises a cylindrical body slidably coupled with the pin shaft and a locking pin for preventing the cylindrical body from sliding along the shaft, wherein the shoulder has a through-hole dimensioned to accommodate the locking pin.

### CROSS-REFERENCE TO RELATED APPLICATIONS

This application claims benefit of U.S. provisional patent application Ser. No. 61/075,225, filed Jun. 24, 2008, which is herein incorporated by reference.

### BACKGROUND

1. Field

Embodiments described herein generally relate to a lift pin and lift pin assembly for spacing substrates from a substrate support.

2. Description of the Related Art

Integrated circuits have evolved into complex devices that include millions of transistors, capacitors and resistors on a single chip. The evolution of chip design results in faster circuitry and greater circuit density. As the demand for integrated circuits continues to rise, chip manufactures have demanded semiconductor process tooling having increased wafer throughput, greater product yield, and more robust processing equipment. To meet demands, tooling is being developed to minimize wafer handoff errors, reduce particle contamination, and increase the service life of tool components.

The lift pins generally reside in guide holes disposed through the substrate support. The upper ends of the lift pins are typically flared to prevent the pins from passing through the guide holes. The lower ends of the lift pins extend below the substrate support and are actuated by a lift plate that contacts the pins at their lower ends. The lift plate is movable in a vertical direction between upper and lower positions. In the upper position, the lift plate moves the lift pins through the guide holes formed through the substrate support to extend the flared ends of the lift pins above the substrate support, thereby lifting the substrate into a spaced apart relation relative to the substrate support to facilitate substrate transfer.

Current floating lift pin designs have difficulty with wafer placement into tight heater pockets causing wafer handoff errors. Fixed floating lift pin designs solve the problem of wafer placement into to tight heater pockets with a resulting increase in lift pin breakage due to an over constrained design which includes metal spring washers that corrode.

Therefore, there is a need in the art for an improved lift pin assembly.

### SUMMARY

Embodiments described herein generally relate to a lift pin assembly for supporting a substrate. In one embodiment, a lift pin assembly for positioning a substrate relative to a substrate support is provided. The lift pin assembly comprises a lift pin having a pin shaft, a foot slidably coupled with the shaft, and a locking pin for preventing the foot from sliding along the shaft.

In another embodiment, a lift pin assembly for positioning a substrate relative to a substrate support is provided. The lift pin assembly comprises a lift pin comprising a pin shaft, a pin head coupled with a first end of the pin shaft for supporting the substrate, and a shoulder coupled with a second end of the pin shaft. The lift pin assembly further comprises a cylindrical body slidably coupled with the pin shaft and a locking pin for preventing the cylindrical body from sliding along the shaft, wherein the shoulder has a through-hole dimensioned to accommodate the locking pin.

In yet another embodiment, a substrate support assembly for manipulating a substrate above thereof is provided. The substrate support assembly comprises a lift pin assembly comprising a lift pin comprising a pin shaft, a pin head coupled with a first end of the pin shaft for supporting the substrate, and a shoulder coupled with a second end of the pin shaft, a cylindrical body slidably coupled with the pin shaft, and a locking pin for preventing the cylindrical body from sliding along the shaft, wherein the shoulder has a through-hole dimensioned to accommodate the locking pin. The substrate support assembly further comprises a substrate support having a plurality of guide holes disposed therethorugh, each guide hole for accommodating a lift pin of the lift pin assembly, a lift plate, and an actuator for controlling the elevation of the lift plate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional view of a deposition chamber with a lift pin assembly according to one embodiment of the present invention;

FIGS. 2A-2C depict cross-sectional views according to various embodiments of a lift pin assembly;

FIG. 3A is a perspective view of a lift pin according to one embodiment of the present invention;

FIG. 3B is a side view of a lift pin according to one embodiment of the present invention;

FIG. 3C is a side view of a lift pin according to one embodiment of the present invention;

FIG. 3D is an enlarged perspective view of one embodiment of the pin head of FIG. 3C;

FIG. 4A is a perspective view of a foot according to one embodiment of the present invention;

FIG. 4B is a bottom view of the foot according to one embodiment of the present invention;

FIG. 4C is a cross-sectional view of one embodiment of the foot taken along line 4C of FIG. 4B.

FIG. 5A is a perspective view of a locking pin according to one embodiment of the present invention;

FIG. 5B is a side view of one embodiment of the locking pin of FIG. 5A;

FIG. 5C is a top view of one embodiment of the locking pin of FIG. 5A; and

FIGS. 6A-6D are cross-sectional views demonstrating installation of a lift pin assembly according to embodiments of the present invention.

To facilitate understanding, identical reference numerals have been used, where possible, to designate identical elements that are common to the figures. It is contemplated that elements disclosed in one embodiment may be beneficially utilized on other embodiment without specific recitation.

### DETAILED DESCRIPTION

Embodiments described herein generally provide an apparatus for processing a semiconductor substrate. The embodiments described herein are illustratively utilized in a processing system, such as a CVD processing system, available from Applied Materials, Inc., of Santa Clara, Calif. However, it should be understood that the embodiments described herein may be incorporated into other chamber configurations such as physical vapor deposition chambers, etch chambers, ion implant chambers, and other semiconductor processing chambers.

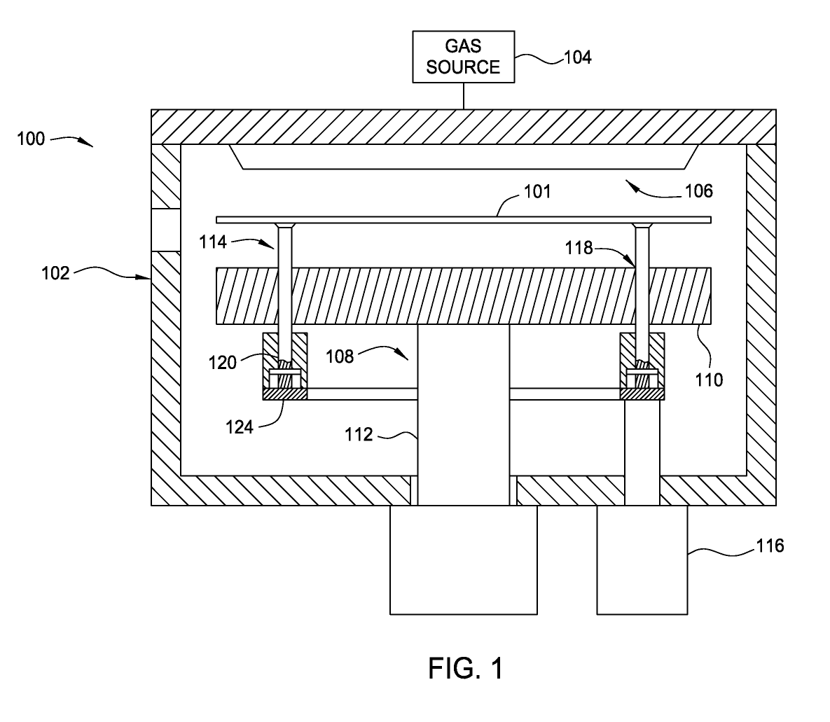

FIG. 1 depicts a cross sectional view of a processing system 100. The system 100 generally comprises a chamber body 102 coupled to a gas source 104. The chamber body 102 is typically a unitary, machined structure fabricated from a rigid block of material such as aluminum. Within the chamber body 102 is a showerhead 106 and a substrate support assembly 108. The showerhead 106 is coupled to the upper surface or lid of the chamber body 102 and provides a uniform flow of gas from the gas source 104 that is dispersed over a substrate 101 positioned on a substrate support assembly 108.

The substrate support assembly 108 generally comprises a substrate support 110 and a stem 112. The stem 112 positions the substrate support 110 within the chamber body 102. The substrate 101 is placed upon the substrate support 110 during processing. The substrate support 110 may be a susceptor, a heater, an electrostatic chuck or a vacuum chuck. Typically, the substrate support 110 is fabricated from a material selected from ceramic, aluminum, stainless steel, and combinations thereof. The substrate support 110 has a plurality of guide holes 118 disposed therethrough, each hole 118 accommodating a lift pin 120 of a lift pin assembly 114.

The lift pin assembly 114 interacts with the substrate support 110 to position the substrate 101 relative to the substrate support 110. The lift pin assembly 114 typically includes the lift pins 120, a lift plate 124 and an actuator 116 for controlling the elevation of the lift plate 124. The elevation of the lift plate 124 is controlled by the actuator 116. The actuator 116 may be a pneumatic cylinder, hydraulic cylinder, lead screw, solenoid, stepper motor or other motion device that is typically positioned outside of the chamber body 102 and adapted to move the lift plate 124. As the lift plate 124 is moved towards the substrate support 110, the lift plate 124 contacts the lower ends of the lift pins 120 to move the lift pins 120 through the substrate support 110. The upper ends of the lift pins 120 move away from the substrate support 110 and lift the substrate 101 into a spaced-apart relation relative to the substrate support 110.

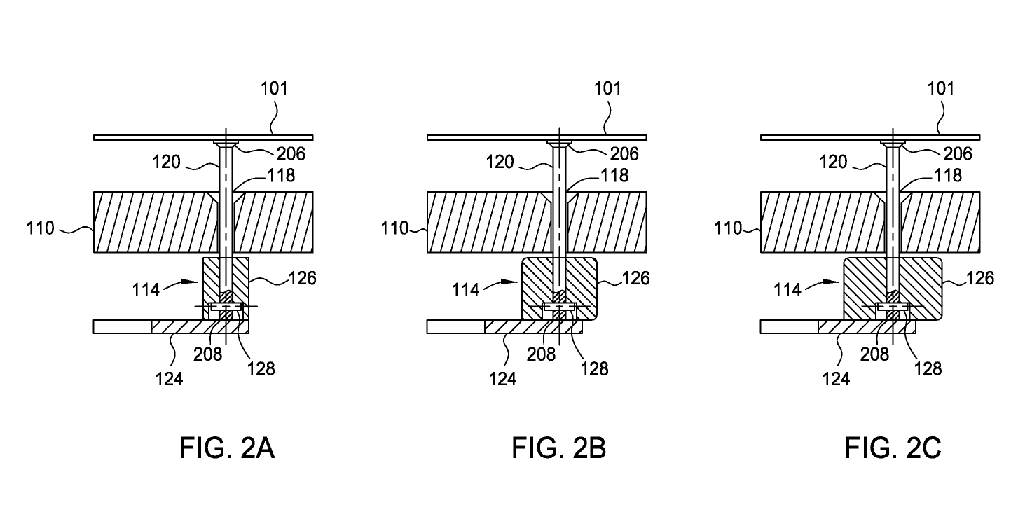

FIGS. 2A-2C depict cross-sectional views according to various embodiments of a lift pin assembly 114. FIG. 2A depicts a cross-sectional view of one embodiment of a lift pin assembly 114 comprising one embodiment of a foot 126 having a small diameter. FIG. 2B depicts a cross-sectional view of one embodiment of a lift pin assembly 114 comprising one embodiment of a foot 126 having a medium diameter. FIG. 2C depicts a cross-sectional view of one embodiment of a lift pin assembly 114 comprising one embodiment of a foot 126 having a large diameter. The lift pin assembly 114 comprises a lift pin 120, a foot 126, and a locking pin 128 for coupling the foot with the lift pin 120.

The plurality of lift pins 120 are disposed axially through the lift pin guide holes 118 formed through the substrate support 110. The guide holes 118 may be integrally formed in the substrate support 110, or may alternatively be defined by an inner passage of a guide bushing (not shown) disposed in the substrate support 110. The lift pin 120 comprises a first end 206 and a second end 208.

The first end 206 of the lift pin 120 is flared to prevent the lift pin 120 from falling through the guide hole 118 disposed through the substrate support 110. The guide hole 118 is typically countersinked to allow the first end 206 to be positioned substantially flush with or slightly recessed from the substrate support 110 when the pin 120 is in a normal position (i.e., retracted relative to the substrate support 110).

The second end 208 of the lift pin 120 extends beyond the underside of the substrate support 110 and is adapted be urged by the lift plate 124 to extend the first end 206 of the lift pin 120 above the substrate support 110. The second end 208 may be rounded, flat or have another shape. In one embodiment, the second end 208 is flat (i.e., oriented perpendicular to the center line of the lift pin 120). The second end 208 is encircled by the foot 126. The foot 126 stands the lift pin 120 on the lift plate 124, thereby maintaining the lift pins 120 substantially parallel to a central axis of the lift pins guide holes 118, advantageously reducing binding and contact between the pin and a lower edge of the guide holes 118. Moreover, the foot 126 allows for easy centering of the lift pin 120 within the lift pin guide hole 118, reducing the likelihood that the lift pin 120 will tilt or lean in the guide hole 118, thereby becoming jammed or scratched.

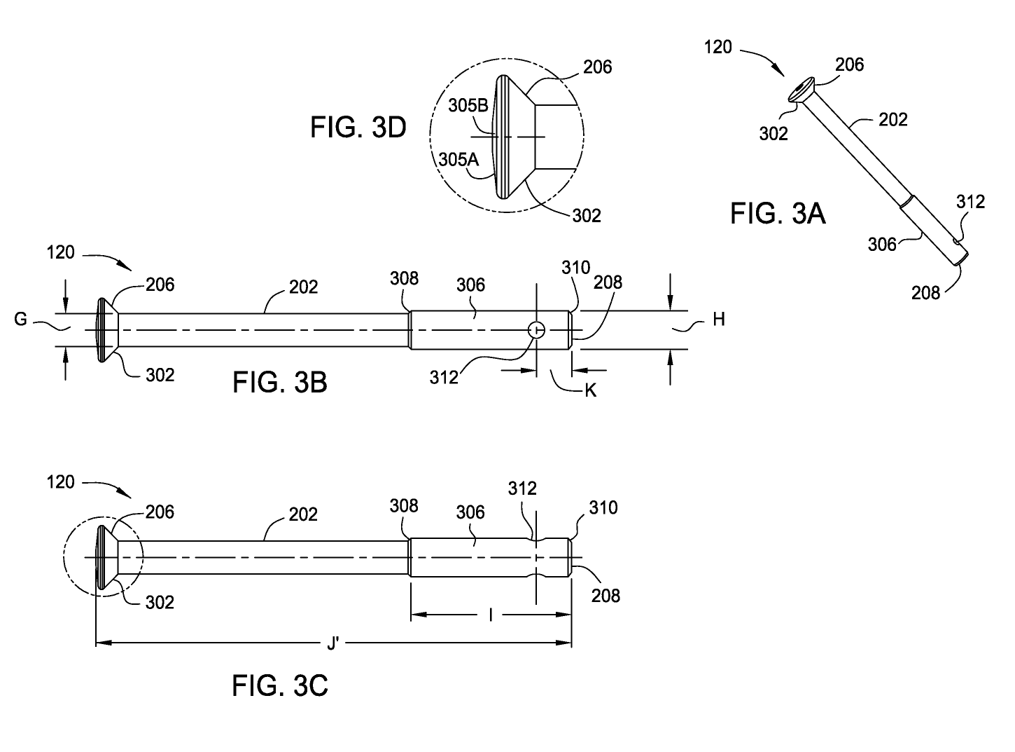

FIG. 3A is a perspective view of a lift pin 120 according to one embodiment of the present invention. FIG. 3B is a side view of a lift pin 120 according to one embodiment of the present invention. FIG. 3C is yet another side view of a lift pin 120 according to one embodiment of the present invention. FIG. 3D is an enlarged perspective view of one embodiment of the pin head 302 of FIG. 3C. The lift pin 120 is typically comprised of ceramic, stainless steel, aluminum, or other suitable material. A cylindrical outer surface of the lift pin 120 may additionally be treated to reduce friction and surface wear. For example, the cylindrical outer surface of the lift pin 120 may be plated, plasma flame sprayed, or electropolished to reduce friction, alter the surface hardness, improve smoothness, and improve resistance to scratching and corrosion.

The lift pin 120 comprises a shaft 202 having a diameter “G” coupled with a first end 206 and a second end 208. The first end 206 of the lift pin 120 comprises a pin head 302. The pin head 302 is the end portion of the pin shaft 202 for supporting the substrate 101. The pin head 302 has a convex support surface 305A, where a flat portion 305B is located on a central, top area thereof. The convex support surface 305A and the flat portion 305B are generally circular areas, but other shapes may be applied.

The second end 208 of the lift pin 120 comprises a shoulder 306 having a diameter “H,” wherein the diameter “H” is greater than the diameter “G” of the shaft 202. The shoulder 306 includes tapered ends 308 and 310. The tapered end 308 transitions the shoulder 306 with the shaft 202. The shoulder 306 has a through-hole 312 dimensioned to accommodate the locking pin 128. In one embodiment, the length “I” of the shoulder is approximately ⅓ of the total length “J” of the lift pin 120. In one embodiment, the distance “K” from the center of the through-hole 312 to the second end 208 of the lift pin is approximately ¼ the length “I” of the shoulder 306.

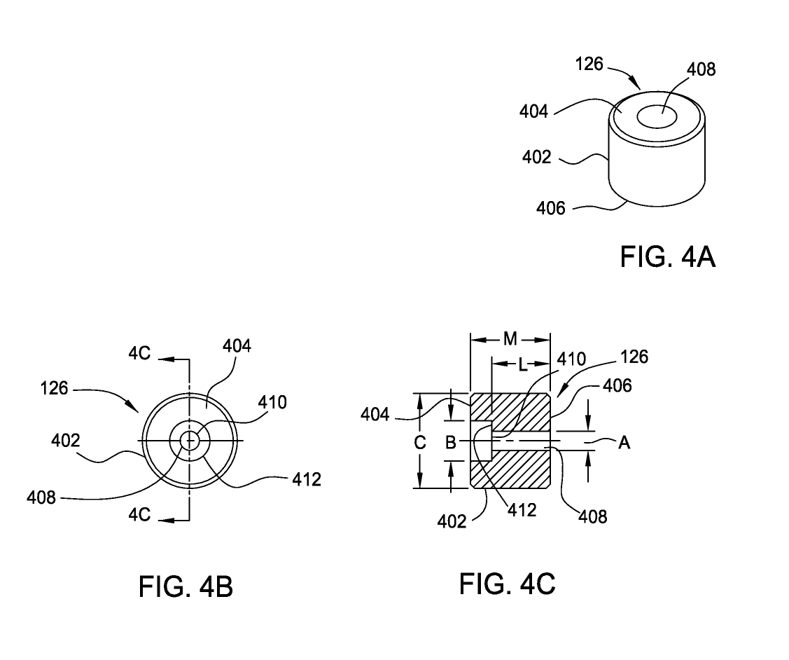

FIG. 4A is a perspective view of a foot 126 according to one embodiment of the present invention. FIG. 4B is a bottom view of the foot 126 according to one embodiment described herein. FIG. 4C is a cross-sectional view of one embodiment of the foot 126 taken along line 4C of FIG. 4B. The foot 126 comprises a cylindrical body 402 with a first surface 404 defining a bottom of the cylindrical body 402 and a second surface 406 defining a top of the cylindrical body 402. The cylindrical body 402 has a diameter “C.” In one embodiment, the first surface 404 defines the bottom the cylindrical body 402 and the second surface 406 defines the top of the cylindrical body 402. In one embodiment, the edge of the first surface 404 and the edge of the second surface 406 may be tapered. The foot 126 is typically comprised of a material selected from ceramic, stainless steel, aluminum, and combinations thereof.

The cylindrical body 402 has a through-hole 408 with a first diameter “A” and a second diameter “B,” wherein the second diameter “B” is greater than the first diameter “A.” The first diameter “A” is dimensioned to accommodate the shoulder 306 of the lift pin 120. The second diameter “B” of the through-hole 408 is dimensioned to accommodate both the shoulder 306 of the lift pin 120 and the locking pin 128 when inserted into the through-hole 312 of the lift pin 120. In one embodiment, a transition point 410 between the first diameter “A” of the through-hole 408 and the second diameter “B” of the through-hole 408 forms a stepped surface 412. The stepped surface 412 may rest on the locking pin 128 when the lift pin assembly 114 is assembled. The through-hole 408 having the first diameter “A” extends from the second surface 406 partially through the cylindrical body 402. In one embodiment, the through-hole 408 having the first diameter “A” has a length “L” approximately ¾ the total length “M” of the cylindrical body 402. The second diameter “B” of the through-hole extends from the first surface 404 of the cylindrical body 402 to the transition point 410 where the stepped surface 412 is formed.

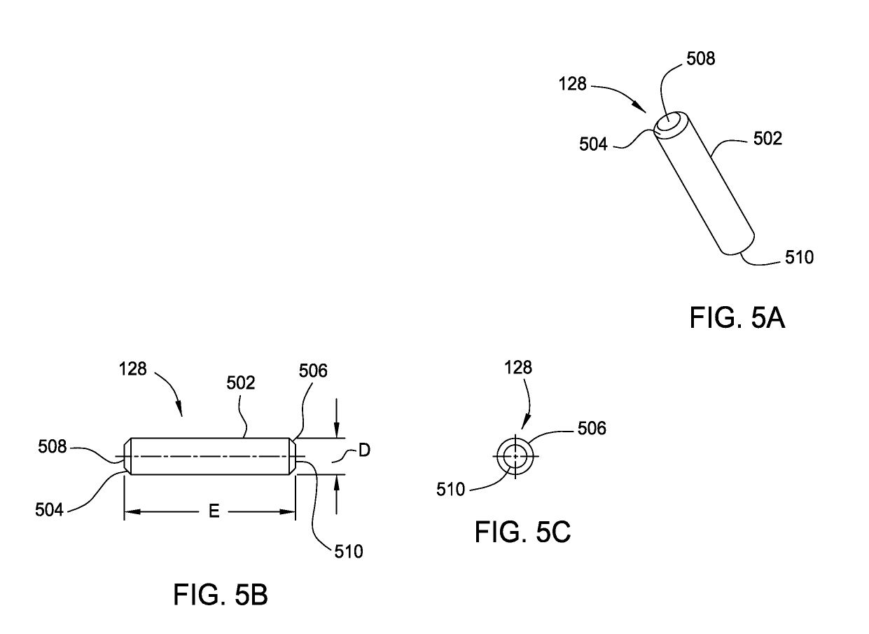

FIG. 5A is a perspective view of a locking pin 128 according to one embodiment described herein. FIG. 5B is a side view of the locking pin 128 of FIG. 5A. FIG. 5C is a top view of the locking pin 128 of FIG. 5A. The locking pin 128 securely couples the foot 126 with the lift pin 120. The locking pin 128 comprises a cylindrical body 502 comprising a first tapered portion 504 leading to a first end 508 and a second tapered portion 506 leading to a second end 510. The diameter “D” of the cylindrical body 502 is dimensioned to fit within the through-hole 312 of the lift pin 120. The length “E” of the locking pin 128 is dimensioned to fit within the second diameter “B” of the through-hole 408. The locking pin 128 is typically comprised of a material selected from ceramic, stainless steel, aluminum, and combinations thereof.

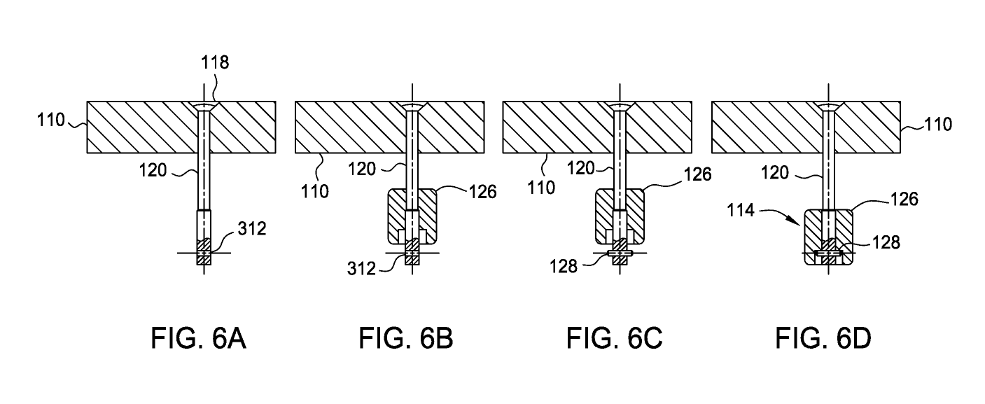

FIGS. 6A-6D are cross-sectional views demonstrating installation of a lift pin assembly 114 according to one embodiment described herein. Installation of the lift pin assembly 114 begins with the lift pin 120 positioned in the guide hole 118 of the substrate support 110. In FIG. 6B, the foot 126 slides up over the shoulder 306 and shaft 202 of the lift pin 120. In FIG. 6C, the locking pin 128 is inserted into the through-hole 312 of the shaft 202 of the lift pin 120 thereby, capturing the locking pin 128. In FIG. 6D, the foot 126 slides down the shoulder 306 and shaft 202 of the lift pin 120 until the stepped surface 412 of the foot 126 rests on the locking pin 128, thereby locking everything together.

According to the forgoing embodiments, a lift pin assembly having the advantages of increased wafer placement accuracy and repeatability is provided. The lift pin assembly also has increased lift pin stability provided by proper length to diameter (L/D) ratios of the lift pin and foot. Further, installation of the lift pin assembly on current systems is very straight forward.

While the foregoing is directed to embodiments of the present invention, other and further embodiments of the invention may be devised without departing from the basic scope thereof, and the scope thereof is determined by the claims that follow.

1. A lift pin assembly for positioning a substrate relative to a substrate support, comprising:
a lift pin having a shaft;
a foot slidably coupled with the shaft; and
a locking pin for preventing the foot from sliding along the shaft.

2. The lift pin assembly of claim 1, wherein the shaft of the lift pin has a through-hole dimensioned to accommodate the locking pin.

3. The lift pin assembly of claim 1, wherein the foot comprises a cylindrical body comprising:
a first surface defining a bottom of the cylindrical body; and a second surface defining a top of the cylindrical body, wherein the cylindrical body has a through-hole having a first diameter dimensioned to accommodate the shaft of the lift pin and a second diameter greater than the first diameter dimensioned to accommodate both the shaft of the lift pin and the locking pin when the locking pin is inserted into the through-hole of the shaft.

4. The lift pin assembly of claim 3, wherein the cylindrical body further comprises a stepped surface formed at a transition point between the first diameter of the through-hole and the second diameter of the through-hole, wherein the stepped surface rests on the locking pin when the locking pin is inserted in the through-hole of the shaft thereby, capturing the locking pin.

5. The lift pin assembly of claim 4, wherein the through-hole having the first diameter extends from the second surface of the cylindrical body partially through the cylindrical body and the second diameter of the through-hole extends from the first surface of the cylindrical body to the transition point where the stepped surface is formed.

6. The lift pin assembly of claim 1, wherein a diameter of the foot is greater than a diameter of the shaft.

7. The lift pin assembly of claim 6, wherein the lift pin and the foot comprise ceramic material.

8. A lift pin assembly for positioning a substrate relative to a substrate support, comprising:
a lift pin comprising:
a pin shaft;
a pin head coupled with a first end of the pin shaft for supporting the substrate; and
a shoulder coupled with a second end of the pin shaft;
a cylindrical body slidably coupled with the pin shaft; and
a locking pin for preventing the cylindrical body from sliding along the shaft, wherein the shoulder has a through-hole dimensioned to accommodate the locking pin.

9. The lift pin assembly of claim 8, wherein the shoulder has a diameter greater than a diameter of the pin shaft.

10. The lift pin assembly of claim 8, wherein the shoulder has a length approximately ⅓ of a length of the lift pin.

11. The lift pin assembly of claim 10, wherein a distance from the center of the through-hole to an end of the shoulder is approximately ¼ a length of the shoulder.

12. The lift pin assembly of claim 8, wherein the cylindrical body comprises:
a first surface defining a bottom of the cylindrical body; and
a second surface defining a top of the cylindrical body, wherein the cylindrical body has a through-hole having a first diameter dimensioned to accommodate the shoulder of the lift pin and a second diameter dimensioned to accommodate both the shoulder of the lift pin and the locking pin when inserted into the through-hole of the lift pin.

13. The lift pin assembly of claim 12, wherein the cylindrical body further comprises a stepped surface formed at a transition point between the first diameter of the through-hole and the second diameter of the through-hole, wherein the stepped surface rests on the locking pin when the locking pin is inserted in the through-hole of the shoulder.

14. The lift pin assembly of claim 13, wherein the through-hole having the first diameter extends from the second surface of the cylindrical body partially through the cylindrical body and the second diameter of the through-hole extends from the first surface of the cylindrical body to the transition point where the stepped surface is formed.

15. The lift pin assembly of claim 8, wherein the pin head has a convex support surface where a flat portion is located on a central, top area of the pin head.

16. The lift pin assembly of claim 15, wherein the convex support surface and the flat portion are generally circular areas.

17. A substrate support assembly for manipulating a substrate above thereof, comprising:
a lift pin assembly comprising:
a lift pin comprising:
a pin shaft;
a pin head coupled with a first end of the pin shaft for supporting the substrate; and
a shoulder coupled with a second end of the pin shaft;
a cylindrical body slidably coupled with the pin shaft; and
a locking pin for preventing the cylindrical body from sliding along the shaft, wherein the shoulder has a through-hole dimensioned to accommodate the locking pin;
a substrate support, having a plurality of guide holes disposed therethrough, each guide hole for accommodating a lift pin of the lift pin assembly;
a lift plate; and
an actuator for controlling the elevation of the lift plate.

18. The lift pin assembly of claim 17, wherein the cylindrical body comprises:
a first surface defining a bottom of the cylindrical body; and
a second surface defining a top of the cylindrical body, wherein the cylindrical body has a through-hole having a first diameter dimensioned to accommodate the shoulder of the lift pin and a second diameter dimensioned to accommodate both the shoulder of the lift pin and the locking pin when inserted into the through-hole of the lift pin.

19. The lift pin assembly of claim 18, wherein the cylindrical body further comprises a stepped surface formed at a transition point between the first diameter of the through-hole and the second diameter of the through-hole, wherein the stepped surface rests on the locking pin when the locking pin is inserted in the through-hole of the shoulder.

20. The lift pin assembly of claim 19, wherein the through-hole having the first diameter extends from the second surface of the cylindrical body partially through the cylindrical body and the second diameter of the through-hole extends from the first surface of the cylindrical body to the transition point where the stepped surface is formed.
